(19) United States
(12) Patent Application Publication
(10) Pub. No.: US 2024/0233823 A9
(43) Pub. Date: Jul. 11, 2024

(54) 3D ARRAY STRUCTURES AND PROCESSES

(71) Applicant: Fu-Chang Hsu, San Jose, CA (US)

(72) Inventor: Fu-Chang Hsu, San Jose, CA (US)

(21) Appl. No.: 18/492,625

(22) Filed: Oct. 23, 2023

Related U.S. Application Data
(60) Provisional application No. 63/418,534, filed on Oct. 22, 2022.
(60) Provisional application No. 63/421,522, filed on Nov. 1, 2022.
(60) Provisional application No. 63/458,634, filed on Apr. 11, 2023.
(60) Provisional application No. 63/459,406, filed on Apr. 14, 2023.
(60) Provisional application No. 63/460,406, filed on Apr. 19, 2023.
(60) Provisional application No. 63/463,040, filed on Apr. 30, 2023.
(60) Provisional application No. 63/465,526, filed on May 10, 2023.
(60) Provisional application No. 63/466,155, filed on May 12, 2023.
(60) Provisional application No. 63/467,004, filed on May 16, 2023.
(60) Provisional application No. 63/542,526, filed on Oct. 5, 2023.

(51) Int. Cl. G11C 16/04; H10B 41/10; H10B 41/20; H10B 41/35; H10B 43/10; H10B 43/20; H10B 43/35

(52) U.S. Cl. CPC G11C 16/0483; H10B 41/10; H10B 41/20; H10B 41/35; H10B 43/10; H10B 43/20; H10B 43/35

(57) ABSTRACT

Various 3D array structures and processes are disclosed. In an embodiment, a word line staircase structure is provided that includes a plurality of word line layers alternately deposited with a plurality of insulating layers to form a stack and a first word line stairstep that includes all the layers of the stack. The staircase structure also includes one or more additional word line stairsteps such that each successive additional word line stairstep is formed to include less layers of the stack than the preceding word line stairstep to form the word line staircase structure. The stairstep structure also includes multiple contact holes formed in each word line stairstep to contact multiple word line layers within that word line stairstep.

### CROSS-REFERENCE TO RELATED APPLICATIONS

This application claims the benefit of priority under 35 U.S.C. 119(e) based upon U.S. Provisional Patent Application having Application No. 63/418,534 filed on Oct. 22, 2022, and entitled “3D Array Structures and Processes,” and U.S. Provisional Patent Application having Application No. 63/421,522 filed on Nov. 1, 2022, and entitled “3D Cell and Array Structures,” and U.S. Provisional Patent Application having Application No. 63/458,634 filed on Apr. 11, 2023, and entitled “3D Cell and Array Structures,” and U.S. Provisional Patent Application having Application No. 63/459,406 filed on Apr. 14, 2023, and entitled “3D Cell and Array Structures and Processes,” and U.S. Provisional Patent Application having Application No. 63/460,406 filed on Apr. 19, 2023, and entitled “3D Memory Cell and Array Structures,” and U.S. Provisional Patent Application having Application No. 63/463,040 filed on Apr. 30, 2023, and entitled “3D Memory Cell and Array Structures,” and U.S. Provisional Patent Application having Application No. 63/465,526 filed on May 10, 2023, and entitled “3D Cell and Array Structures,” and U.S. Provisional Patent Application having Application No. 63/466,155 filed on May 12, 2023, and entitled “3D Cell and Array Structures,” and U.S. Provisional Patent Application having Application No. 63/467,004 filed on May 16, 2023, and entitled “3D Cell and Array Structures,” and U.S. Provisional Patent Application having Application No. 63/542,526 filed on Oct. 5, 2023, and entitled “3D Array Structures and Processes,” all of which are hereby incorporated herein by reference in their entireties.

### FIELD OF THE INVENTION

The exemplary embodiments of the present invention relate generally to the field of memory, and more specifically to memory cells and array structures and associated processes.

### BACKGROUND OF THE INVENTION

With the increasing complexity and density of electronic circuits, memory size, complexity, and cost are important considerations. One approach to increase memory capacity is to use a three-dimensional (3D) array structure. However, efficient, and cost-effective 3D array structures have not been fully realized.

### SUMMARY

In various exemplary embodiments, 3D array structures and processes are disclosed. In one embodiment, a 3D staircase array structure is formed, and multiple novel processes are performed to form multiple vertical contacts to each stairstep of the staircase. Embodiments of the invention can be applied to various 3D array structures, such as 3D NAND flash memory. For example, in additional to 3D NAND flash memory, embodiments of the invention are applicable to other suitable 3D array structures, such as 3D NOR flash memory, 3D resistive random-access memory (RRAM), 3D ferroelectric random-access memory (FRAM), 3D phase-change memory (PCM), 3D artificial neural network array (ANN), and many other 3D array structures.

In an exemplary embodiment, a word line staircase structure is provided that includes a plurality of word line layers alternately deposited with a plurality of insulating layers to form a stack. A first word line stairstep includes all the layers of the stack. The staircase structure also includes one or more additional word line stairsteps such that each successive additional word line stairstep is formed to include less layers of the stack than the preceding word line stairstep to form the word line staircase structure. The stairstep structure also includes multiple contact holes formed in each word line stairstep to contact multiple word line layers within that word line stairstep.

In an exemplary embodiment, an array structure is formed by a process comprising operations of alternately depositing word line layers and insulating layers to form a stack, removing selected portions of the word line layers and insulating layers to form a word line staircase structure having multiple word line stairsteps, depositing a thick insulating layer over the word line staircase structure, forming holes from a top surface of the thick insulating layer to top surfaces of the word line stairsteps such that multiple holes are formed to each word line stairstep, and etching the word line staircase structure through the holes so that depths of selected holes are increased to reach selected word line layers of the stack.

Additional features and benefits of the exemplary embodiments of the present invention will become apparent from the detailed description, figures and claims set forth below.

### BRIEF DESCRIPTION OF THE DRAWINGS

The exemplary embodiments of the present invention will be understood more fully from the detailed description given below and from the accompanying drawings of various embodiments of the invention, which, however, should not be taken to limit the invention to the specific embodiments, but are for explanation and understanding only.

FIG. 1A shows an embodiment of a word line staircase structure of a 3D array according to the invention.

FIG. 1B shows an embodiment of an upper structure of a word line staircase.

FIG. 2 shows an exemplary cross-section view of an embodiment of a word line staircase.

FIGS. 3A-B show detailed embodiments of a staircase structure shown in FIG. 2.

FIGS. 4A-K show embodiments of process steps configured to form word line contacts according to the invention.

FIG. 4L illustrates process steps configured to etch contact holes of a staircase structure in the Y-direction.

FIG. 5A illustrates how multiple sacrificial layers are inserted and deposited on top of word line layers.

FIG. 5B-D illustrates how a hard mask is etched using an isotropic etching process.

FIG. 6 shows a top view of an embodiment of contact holes formed by the processes described above.

FIGS. 7A-B illustrate aspects of “multiple pull-back” etching operations.

FIGS. 8A-C show embodiments illustrating “triple pull-back” etching operations.

### DETAILED DESCRIPTION

Those of ordinary skilled in the art will realize that the following detailed description is illustrative only and is not intended to be in any way limiting. Other embodiments of the present invention will readily suggest themselves to skilled persons having the benefit of this disclosure. Reference will now be made in detail to implementations of the exemplary embodiments of the present invention as illustrated in the accompanying drawings. The same reference indicators or numbers will be used throughout the drawings and the following detailed description to refer to the same or like parts.

The conventional 3D NAND flash memory comprises multiple word line (WL) layers. For example, advanced 3D NAND flash memory can have more than 200 word line layers. These word line layers need to be connected to word line decoder circuits through long contacts. Conventional processes require a very long process time and misalignment of contact holes may occur. In various exemplary embodiments, novel processes are provided to form the word line layer connections while eliminating misalignment problems.

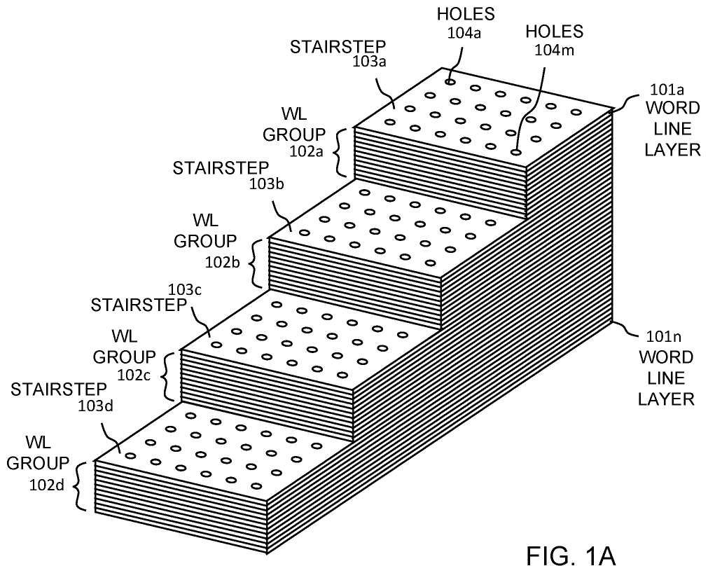

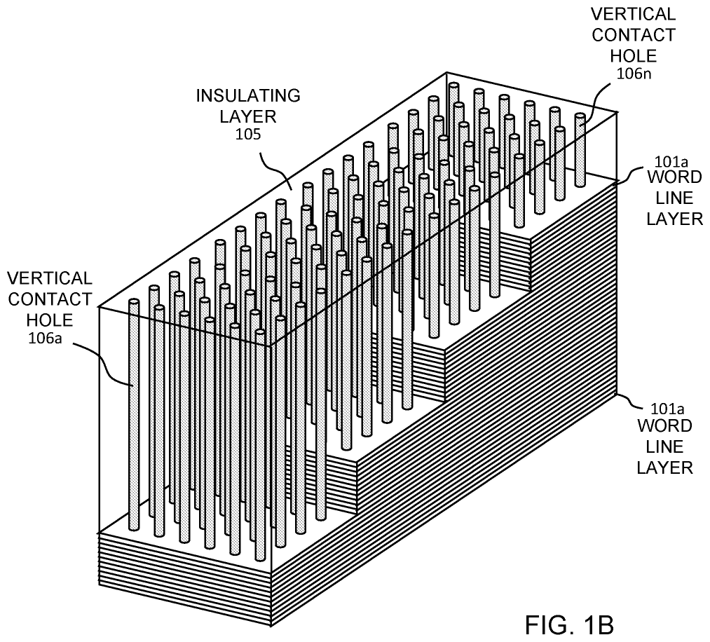

FIG. 1A shows an embodiment of a word line staircase structure of a 3D array according to the invention. It will be assumed that the 3D array comprises multiple word line layers 101a to 101n. In one embodiment, the word line layers 101a-n are separated by insulating layers. The word line layers are divided into multiple word line groups 102a to 102d. Each word line group is etched to form a stairstep, such as stairsteps 103a to 103d. For each word line group, multiple contact holes or openings, such as holes 104a to 104m, are formed to form contacts with the word line layers in that group. For example, the contact holes 104a to 104m can be used to form contacts with the word line layers in the word line group 102a.

FIG. 1B shows an upper structure formed on the word line staircase array. In an embodiment, the staircase is covered by a thick insulting layer 105 comprising material such as oxide material. Multiple vertical contact holes 106a to 106n are formed in the insulating layer 105 by using a deep trench or dry etch process to connect with the contact holes in the staircase, such as contact holes 104a to 104m shown in FIG. 1A. The contact holes 106a to 106n are filled with conductor material, such as metal material, to form contacts to connect each word line layer 101a to 101n to conductive layers (not shown) formed on top of the insulating layer 105.

In various embodiments, there are several advantages of the staircase structure shown in FIG. 1A over conventional art. First, the contact holes, such as holes 104a to 104m in the multiple word line groups 102a to 102d can be formed together. This greatly reduces the process steps and process time to form these contact holes. For example, if the word line layers are divided into 16 groups of word line layers, the process steps and process time can be reduced to 1/16 of the time needed for a conventional structure.

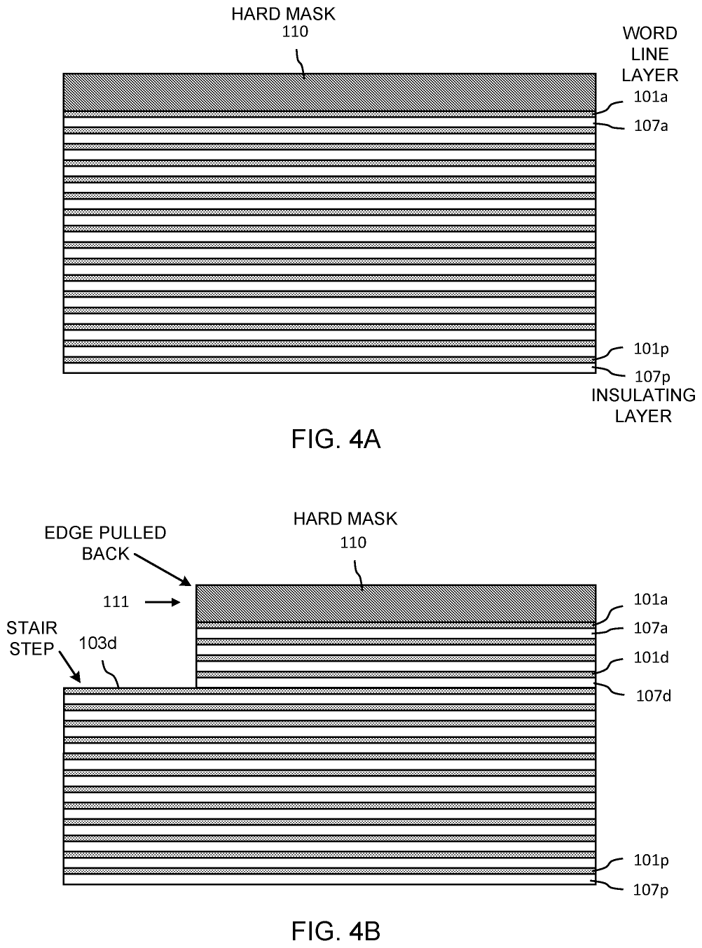

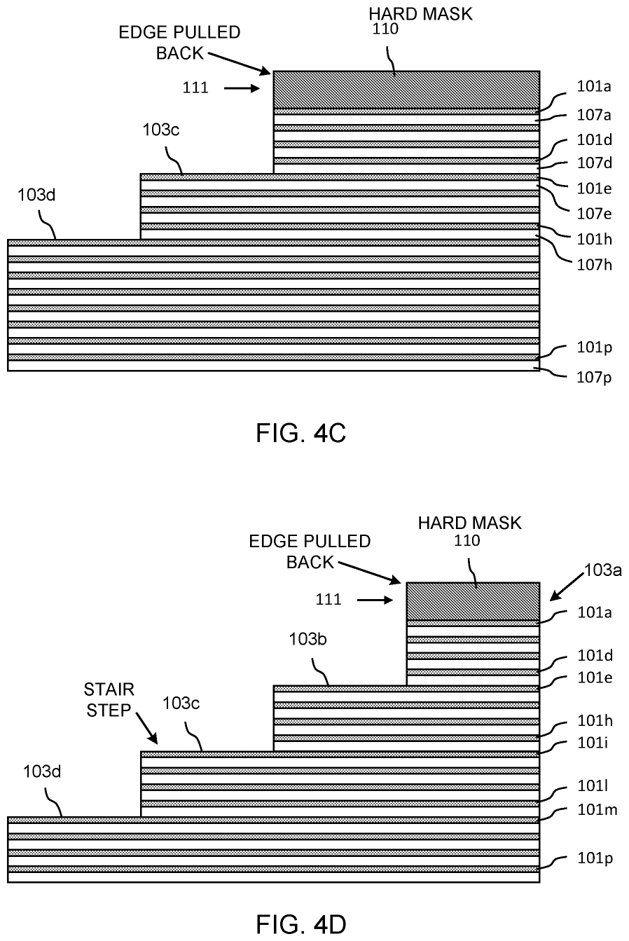

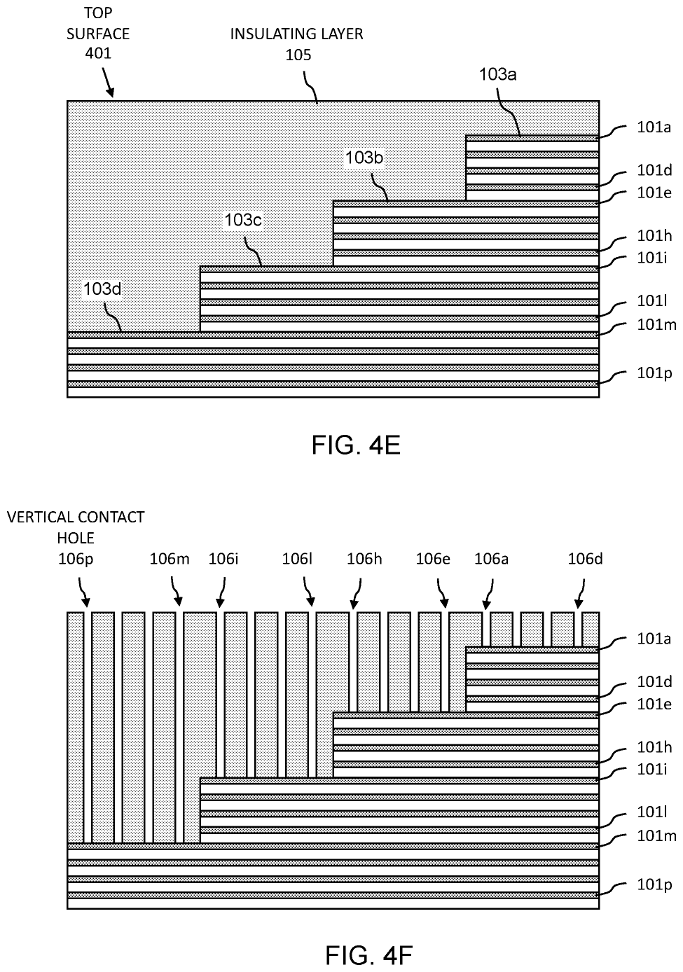

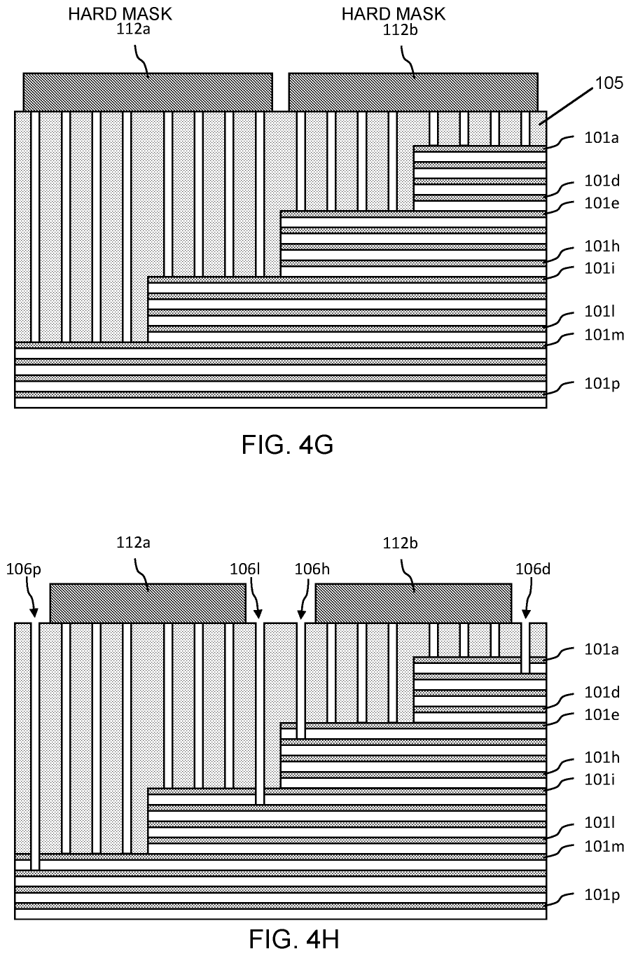

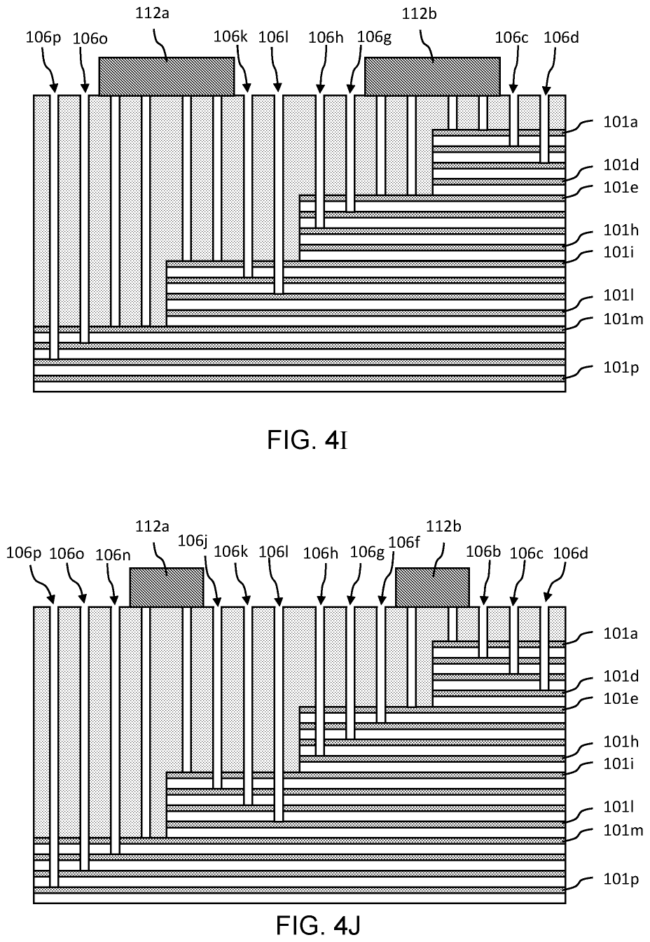

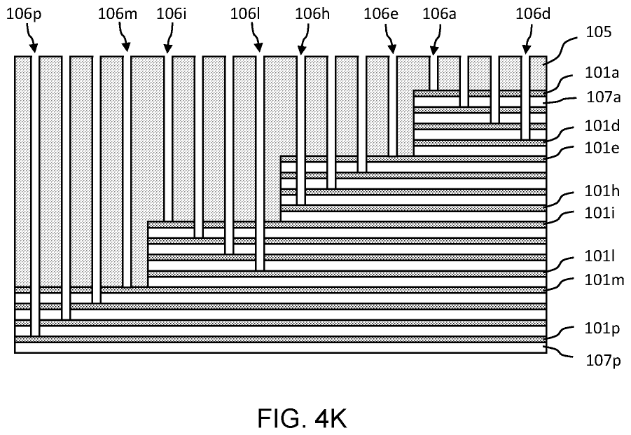

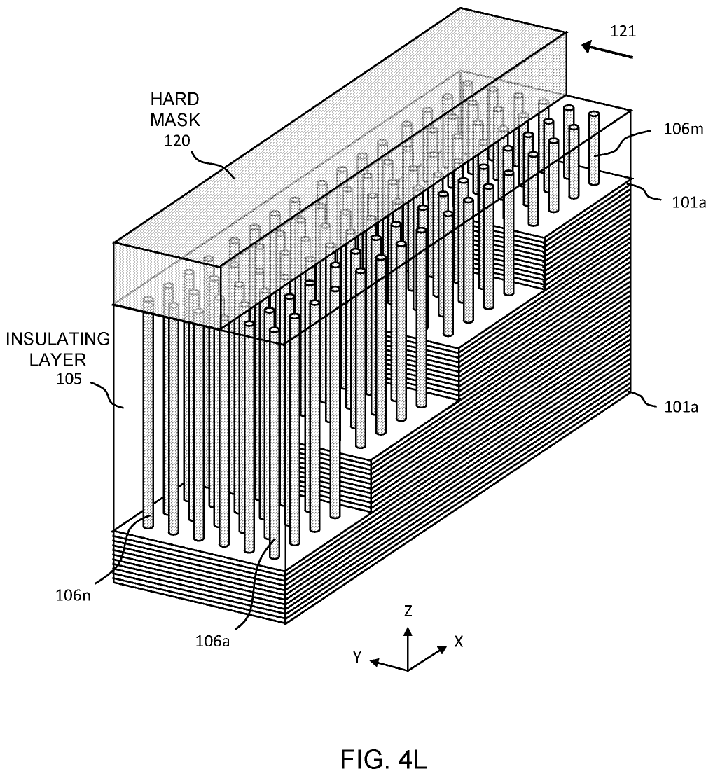

Second, the contact holes in the word lines, such as holes 104a to 104n in the staircase array shown in FIG. 1A, self-align with the vertical contact holes in the insulating layer, such as holes 106a to 106n shown in FIG. 1B. Self-alignment occurs because the holes in the staircase array and the vertical contacts in the insulator 105 are created together at the same time. Therefore, the misalignment problem between the vertical contacts and the staircase experienced with a conventional structure is eliminated. This greatly reduces the layout size of the staircase, and it also improves the process yield. Detailed process steps are provided in the description of FIGS. 4A-K.

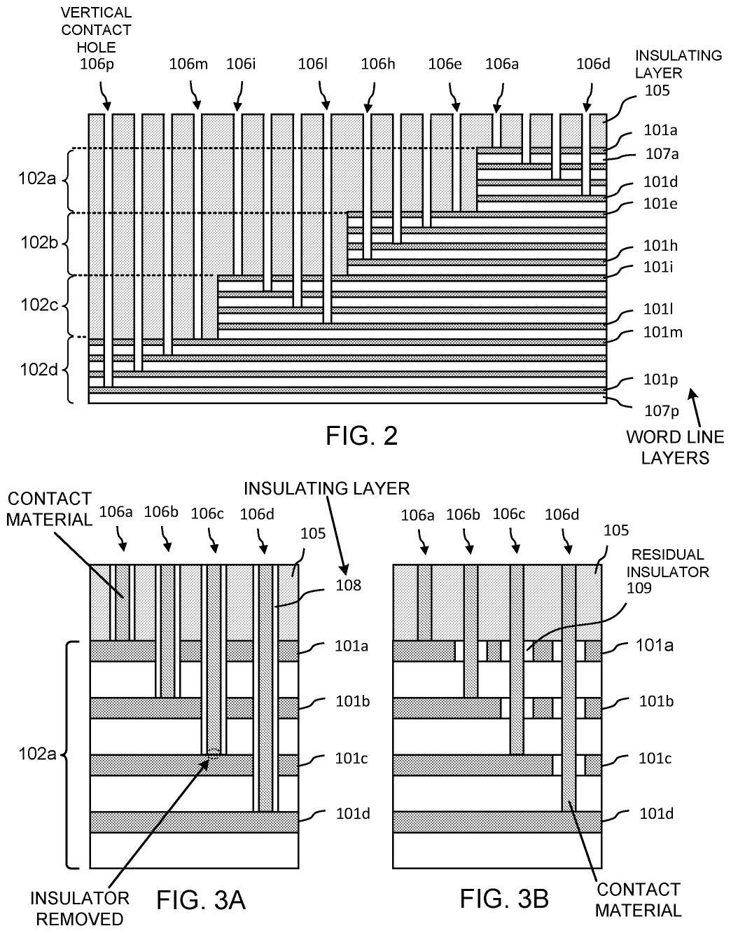

FIG. 2 shows an exemplary cross-section view of an embodiment of a word line staircase array and insulating layer 105 having vertical word line contact holes 106 formed according to the invention. The first group 102a of word lines 101a to 101d are connected to the contact holes 106a to 106d. The second group 102b of word lines 101e to 101h are connected to the contact holes 106e to 106h. The third group 102c of word lines 101i to 1011 are connected to the contact holes 106i to 1061. The fourth group 102d of word lines 101m to 101p are connected to the contact holes 106m to 106p. Also shown are insulating layers 107a to 107p comprising material such as oxide material between the word line layers 101a to 101p.

FIGS. 3A-B show detailed embodiments illustrating the formation of word line contacts, such as contacts 106a to 106d, in the staircase structure 102a and insulating layer 105 shown in FIG. 2.

FIG. 3A shows a detailed side view of the first word line group 102a of the staircase structure shown in FIG. 2. An insulating layer 108 comprising material such as oxide material is formed on the sidewall of the vertical contact holes 106a to 106d by using a thin-film deposition process. Next, an anisotropic etching process, such as reactive ion etching RIE or dry etching, is performed to remove the insulting layer 108 that is deposited at the bottom of the contact holes 106a to 106d. Next, the contact holes 106a to 106d are filled with contact material, such as metal material, using a deposition process to form the word line contacts.

FIG. 3B shows another embodiment of the first word line group 102a of the staircase structure shown in FIG. 2. In this embodiment, after the contact holes 106a to 106d are formed, an isotropic etching process such as wet etching is performed through the contact holes 106a to 106d to selectively etch the word line layers 101a to 101d to form recesses at the regions that will be later occupied by the residual insulator 109. Next, the contact holes and the recesses are filled with the insulator material, such as oxide material. Next, an anisotropic etching process such as dry etching is performed to remove the insulator in the vertical contact holes leaving a residual insulator material 109 inside the recess regions. Next, the contact holes 106a to 106d are filled with contact material such as metal material using a deposition process to form the word line contacts.

FIGS. 4A-K shows an embodiment of process steps configured to form the word line contacts according to the invention.

FIG. 4A illustrates how multiple word line layers 101a to 101p such as metal layers, and multiple insulating layers 107a to 107p such as oxide layers are alternately deposited to form a stack. Next, a hard mask 110 for a pull-back etching operation is formed on top of the stack. In one embodiment, the hard mask 110 is very thick to allow an isotropic etching process, such as wet etching, to ‘pull back’ the edge of the mask without using lithography steps. Because the etching is isotropic, a top portion of the mask will also be etched. Therefore, a very thick hard mask 110 is used to allow several iterations of the pull-back etching process. For illustration purposes, the figures only show that pull-back etching occurs at the edge of the hard mask 110. The reduction of the thickness of the hard mask 110 due to the etching process is not shown.

FIG. 4B illustrates how the hard mask 110 is etched by using an isotropic etching process, such as wet etching, to pull back the edge of the hard mask 110 in the direction shown by the arrow 111. Next, an anisotropic etching process, such as dry etching, is performed to etch the area not protected by the hard mask 110 to etch four word line layers 101a to 101d and four insulating layers 107a to 107d to form the word line stairstep 103d.

FIG. 4C illustrates how the hard mask 110 is pulled back in the direction shown by the arrow 111 again. Next, an anisotropic etching process, such as dry etching, is performed using the hard mask 110 to etch four more word line layers 101e to 101h and four more insulating layers 107e to 107h in the area of the word line stairstep 103d. The etching process will also etch the word line layers 101a to 101d and four insulating layers 107a to 107d to form the word line stairstep 103c.

FIG. 4D illustrates how the hard mask 110 is pulled back in the direction shown by the arrow 111 again. Next, an anisotropic etching process, such as dry etching is performed using the hard mask 110 to etch four more word line layers and four more insulating layers. This will form the word line stairstep 103b. This etching process will also move the word line stairsteps 103d and 103c lower. Next, the hard mask 110 is removed and the stairsteps 103a to 103d are formed.

FIG. 4E illustrates how a thick insulating layer 105 comprising material such as oxide material is deposited on the top of the staircase array. A planarization process, such as chemical mechanical polishing (CMP), is performed to flatten the top surface 401 of the insulating layer 105.

FIG. 4F illustrates how vertical contact holes 106a to 106p are patterned by using lithography and then formed by using an anisotropic etching process, such as deep trench etching, to etch through the insulating layer 105 as shown to form the vertical contact holes.

FIG. 4G illustrates how a hard mask layer is deposited and pattern-etched to form the hard masks 112a and 112b on top of the insulating layer 105 for pull-back etching operations.

FIG. 4H illustrates how the hard masks 112a and 112b are etched by using an isotropic etching process, such as wet etching, to pull back the edges of the hard masks to expose a portion of the contact holes, such as contact holes 106d, 106h, 1061, and 106p. Next, an anisotropic etching process, such as dry etching, is performed using the hard masks 112a and 112b to cover a portion of the insulating layer to etch one word line layer and one insulating layer under the contact holes 106d, 106h, 1061, and 106p.

FIG. 4I illustrates how the hard masks 112a and 112b are pulled back again to expose four more the contact holes 106c, 106g, 106k, and 106o. Next, an anisotropic etching process, such as dry etching, is performed using the hard masks 112a and 112b to cover a portion of the insulating layer to etch one word line layer and one insulating layer under the contact holes 106c, 106d, 106g, 106h, 106k, 1061, 106o, and 106p.

FIG. 4J illustrates how the hard masks 112a and 112b are pulled back again to expose four more the contact holes 106b, 106f, 106j, and 106n. Next, an anisotropic etching process, such as dry etching, is performed using the hard masks 112a and 112b to cover a portion of the insulating layer to etch one word line layer and one insulating layer under the contact holes 106b, 106c, 106d, 106f, 106g, 106h, 106j, 106k, 1061, 106m, 106o, and 106p.

FIG. 4K illustrates a structure that is formed when the remaining portions of the hard masks 112a and 112b are removed by using an isotropic etching process. The contact holes 106a to 106p are in contact with the word line layers 101a to 101p.

The process steps shown in FIGS. 4A-K are configured to etch the contact holes of the staircase structure in the X-direction, such as etching the contact holes 106a to 106m as described above, so that the contact holes make contact with different word line layers.

FIG. 4L illustrates process steps configured to etch the contact holes of the staircase structure in the Y-direction, for instance, to form contact holes 106a to 106n, so that these contact holes make contact with different word line layers. For Y-direction etching, a hard mask 120 is formed on top of the insulating layer 105. A pull-back etch operation is performed as described above to pull back the hard mask 120 in the Y-direction shown by the arrow 121. Each pull-back operation reveals one row of contact holes, such as holes 106a to 106m. Next, an etching process as describe above is performed to etch through the contact holes 106a to 106m to etch one or multiple word line layers and insulating layers under the contact holes. As a result, the contact holes 106a to 106m are configured to contact with selected lower word line layers. By repeating the previously described pull-back process in the Y-direction, the contact holes such as holes 106a to 106n are etched to contact with different word line layers as desired.

By combining the process steps illustrated in FIGS. 4A-K and FIG. 4L, contact holes in the X and Y directions can be configured to contact any of the word line layers. For example, referring to FIG. 1A, it will be assumed that the contact holes 104a to 104m are configured as a 4×6 matrix in X and Y directions. In an embodiment, the steps shown in FIGS. 4A-K are used to perform 4 pull-back etching in X direction, and the step shown in FIG. 4L are used to perform 6 pull-back etching in Y direction. As a result, 24 contact holes will be formed to contact with 24 word line layers. In one embodiment, the process steps shown in FIG. 4L are performed before the process steps shown in FIGS. 4A-K. In another embodiment, the process steps shown in FIG. 4L are performed after the process steps shown in FIGS. 4A-K.

In the embodiment of the process steps shown in FIGS. 4A-D, after each pull-back of the hard mask 110, four word line layers and four insulating layers are etched. This requires eight iterations of the etching steps. If one word line group comprises 50 layers, it will require 100 iterations of the etching steps. If an array comprises 4 word line groups, it will require 400 iterations of the etching steps.

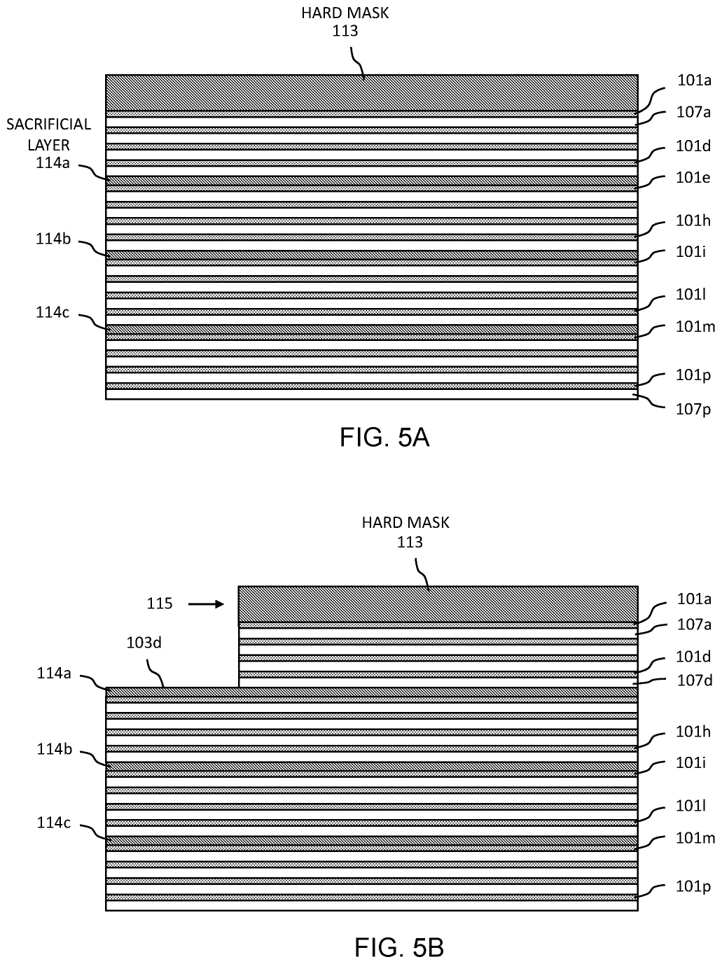

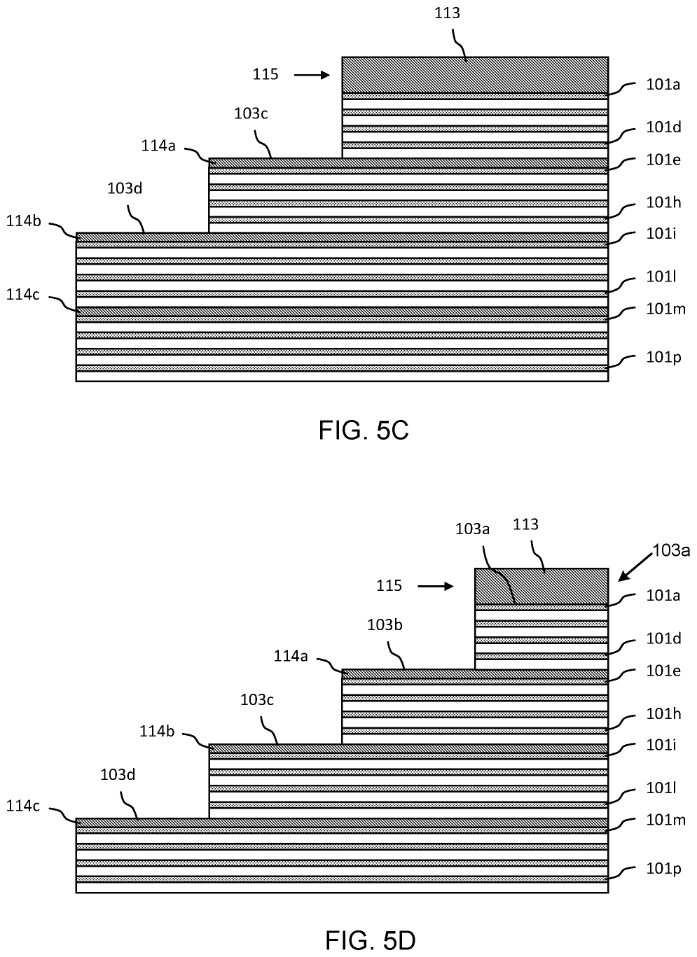

FIGS. 5A-D show embodiments of process steps configured to reduce the number of the etching steps used to form the word line stairsteps according to the invention.

FIG. 5A illustrates that in the process of depositing the word line layers 101a to 101p and the insulating layers 107a to 107p, multiple sacrificial layers 114a to 114c are inserted and deposited on top of the word line layers 101e, 101i, and 101m. As a result, the word line layers 101e, 101i, and 101m form the top layer of the bottom three groups.

In one embodiment, the sacrificial layers 114a to 114c have higher etching selectivity than the word line layers 101a to 101p and the insulating layers 107a to 107p. For example, in one embodiment, the word line layers 101a to 101p are metal layers, the insulating layers 107a to 107p are oxide layers, and the sacrificial layers 114a to 114c are nitride layers. After the word line stack is formed, a thick hard mask 113 for pull-back etching operations is formed on top of the array.

FIG. 5B illustrates how the hard mask 113 is etched by using an isotropic etching process, such as wet etching, to pull back the edge of the hard mask 113 in the direction shown by the arrow 115. Next, an anisotropic etching process, such as deep trench etching, is performed using the hard mask 113 to cover a portion of the stack to selectively etch all the word line layers 101a to 101d and insulating layers 107a to 107d above the sacrificial layer 114a.

In one embodiment, the selected etching solution etches the materials of the word line layers 101a to 101d and insulating layers 107a to 107d but cannot etch the sacrificial layer 114a. Therefore, only one etching step is needed to etch four word line and insulating layers, and the etching automatically stops at the sacrificial layer 114a. After that, an anisotropic etching process such, as dry etching, is performed to etch the sacrificial layer 114a on top of the stairstep 103d.

FIG. 5C illustrates how the hard mask 113 is pulled back in the direction shown by the arrow 115 again. The previously described etching process is performed to etch all the word line layers and insulating layers above both of the second sacrificial layer 114b on top of the stairstep 103d and the first sacrificial layer 114a on top of the stairstep 103c. Next, an anisotropic etching process, such as dry etching, is performed to etch the sacrificial layer 114b on top of the stairstep 103d and the sacrificial layer 114a on top of the stairstep 103c.

FIG. 5D illustrates how the hard mask 113 is pulled back again in the direction shown by the arrow 115. The previously described etching process is performed to etch all the word line layers and insulating layers above the third sacrificial layer 114c on top of the stairstep 103d and the second sacrificial layer 114b on top of the stairstep 103c and the first sacrificial layer 114a on top of the stairstep 103b. Next, an anisotropic etching process, such as dry etching, is performed to etch the sacrificial layer 114c on top of the stairstep 103d and the sacrificial layer 114b on top of the stairstep 103c and the sacrificial layer 114a on top of the stairstep 103b.

After performing the process steps described above, the hard mask 113 is removed to reveal the stairstep 103a. Next, the process steps shown in FIGS. 4E-K are performed to form the word line layer contact holes such as contact holes 106a to 106p shown in FIG. 4K.

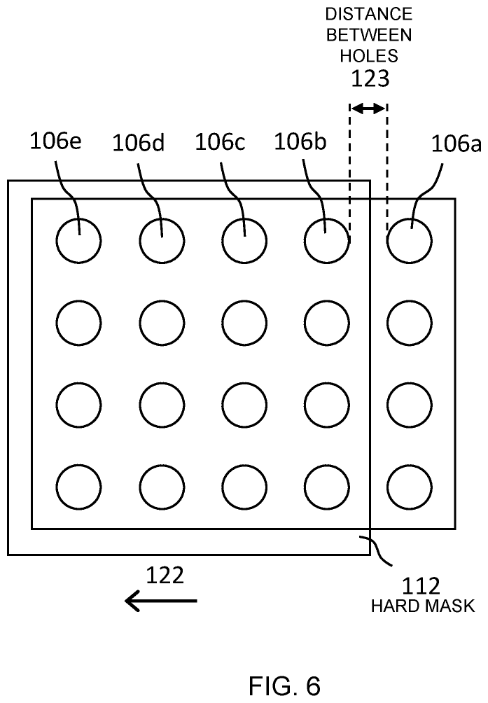

FIG. 6 shows a top view of an embodiment of the contact holes 106a to 106e formed by the processes described above. During the pull-back etch operation, the hard mask 112 is pulled back in the direction shown by the arrow 122. The distance of each pullback must be accurately controlled so that the edge of the hard mask 112 is located between two rows of contact holes, and within the distance 123 between holes as shown. This requirement creates a huge challenge for the pull-back etching process and reduces the process yield. As a result, a large distance 123 may be used to improve the process yield, which results in increased die size.

To address the required accuracy of the pull-back distance, embodiments of the invention provide novel “multiple pull-back” etching operations.

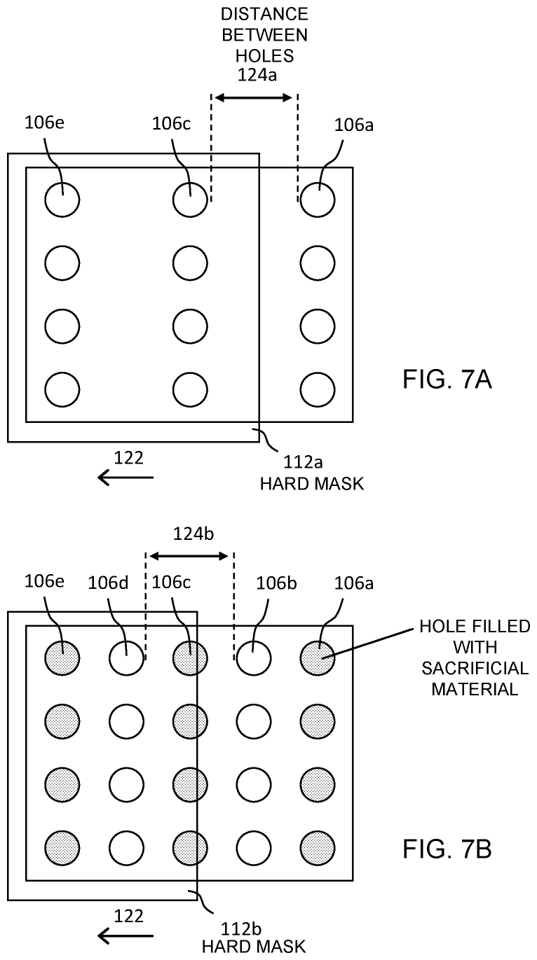

FIG. 7A shows a top view of an embodiment of the contact holes 106a to 106e formed by the processes described above to illustrate aspects of “multiple pull-back” etching operations. First, only the even contact holes 106a, 106c, and 106e are patterned and formed. In the first pull-back operation, the first hard mask 112a is sequentially pulled back to etch the even contact holes 106a, 106c, and 106e. Etching only the even contact holes increases the distance between the contact holes, as shown 124a, and thus the process yield is increased because the pull-back accuracy requirement is easier to meet.

FIG. 7B shows operations that are performed after the first pull-back etch operations in which the even contact holes 106a, 106c, and 106e are filled with a sacrificial material. Next, the odd contact holes 106b and 106d are patterned and formed. In an embodiment, a second hard mask 112b is formed and sequentially pulled back to form the odd contact holes 106b and 106d. This increases the distance between these contact holes, as shown by the distance 124b, thus the process yield is increased.

After the second pull-back etch operation, the sacrificial materials in all the contact holes are etched. Next, the following process are performed to form the contact structures shown in FIG. 3A-B.

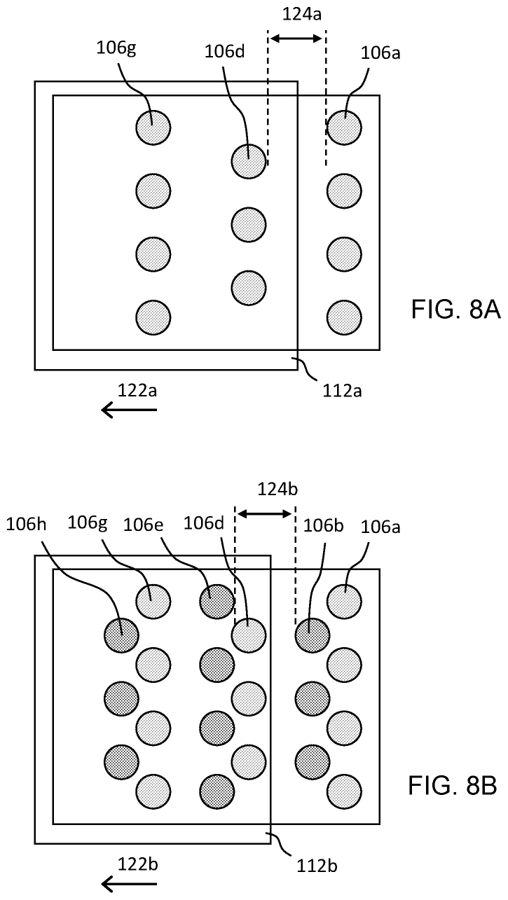

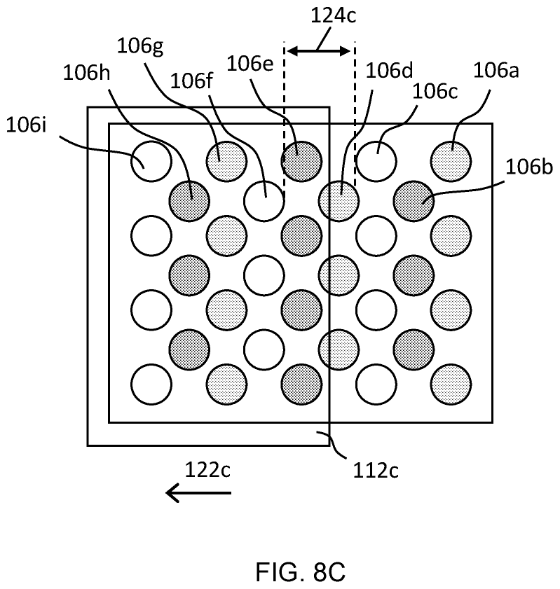

FIGS. 8A-C show embodiments illustrating “triple pull-back” etching operations.

FIG. 8A illustrates how a first group of contact holes, such as contact holes 106a, 106d, and 106g are formed and sequentially pull-back etched using the first hard mask 112a. Also shown is the distance 124a between the contact holes. After the first pull-back etching operations are completed, the first group of contact holes, such as hole 106a, 106d, and 106g are filled with a sacrificial material.

FIG. 8B illustrates how a second group of contact holes such as 106b, 106e, and 106h are formed and sequentially pull-back etched by using the second hard mask 112b. Also shown is the distance 124b between the second group of contact holes. After the second pull-back etch operations are completed, the second group of contact holes, such as holes 106b, 106e, and 106h are filled with a sacrificial material.

FIG. 8C illustrates how a third group of contact holes, such as holes 106c, 106f, and 106i are formed and sequentially pull-back etched by using the third hard mask 112c. Also shown is the distance 124c between the contact holes. By using this configuration, pull-back etching of selected contact hole groups can be performed to meet the tight pitch requirements between contact holes with high yield.

After the third pull-back etching operations are completed, the sacrificial materials in the first group and second group of contact holes are removed by etching. Next, additional processes are performed to form the contact structures shown in FIGS. 3A-B.

It should be not that although embodiments the invention described herein use word line layers as an example, the invention may be applied to the connections of any other layers, such as bit line (BL) layers or source line (SL) layers. In addition, the array geometry, process steps, and process orders are shown as examples only, any minor modifications or variations are within the scope of the invention.

While exemplary embodiments of the present invention have been shown and described, it will be obvious to those with ordinary skills in the art that based upon the teachings herein, changes and modifications may be made without departing from the exemplary embodiments and their broader aspects. Therefore, the appended claims are intended to encompass within their scope all such changes and modifications as are within the true spirit and scope of the exemplary embodiments of the present invention.

What is claimed is:

1. A word line staircase structure, comprising:
a plurality of word line layers alternately deposited with a plurality of insulating layers to form a stack;
a first word line stairstep that includes all the layers of the stack;
one or more additional word line stairsteps, wherein each successive additional word line stairstep is formed to include less layers of the stack than a preceding word line stairstep to form the word line staircase structure; and
multiple contact holes formed in each word line stairstep to contact multiple word line layers within that word line stairstep.

2. An array structure formed by a process comprising:
alternately depositing word line layers and insulating layers to form a stack;
removing selected portions of the word line layers and insulating layers to form a word line staircase structure having multiple word line stairsteps;
depositing a thick insulating layer over the word line staircase structure;
forming holes from a top surface of the thick insulating layer to top surfaces of the word line stairsteps, wherein multiple holes are formed to each word line stairstep and
etching the word line staircase structure through the holes so that depths of selected holes are increased to reach selected word line layers of the stack.
